(19) United States
(12) Patent Application Publication
(10) Pub. No.: US 2007/0272959 A1
(43) Pub. Date: Nov. 29, 2007

(54) FERROELECTRIC MEMORY CELL AND MANUFACTURING METHOD THEREOF

(76) Inventors: Osamu Hidaka, Tokyo (JP); Iwao Kunishima, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/753,292

(22) Filed: May 24, 2007

(30) Foreign Application Priority Data
May 29, 2006 (JP) P2006-148445

(51) Int. Cl. H01L 29/94

(52) U.S. Cl. 257/295

(57) ABSTRACT

A method of manufacturing a ferroelectric memory cell includes: forming device isolation regions; and source/drain regions; forming a gate insulating film on the semiconductor substrate; forming a gate electrode on the gate insulating film; forming; forming a contact plug to be connected to one of the source/drain regions. The method further includes: forming a lower electrode to be connected to the contact plug; depositing a sol-gel solution containing a ferroelectric minute crystal on the lower electrode to form a ferroelectric film; forming an upper electrode on the ferroelectric film; forming a second interlayer insulating film. The method further includes: forming a capacitor contact plug to be connected to the upper electrode; forming a substrate contact plug to be connected to the other one of the source/drain regions; and forming first and second wiring layers to be connected to the capacitor contact plug and the substrate contact plug, respectively.

### CROSS-REFERENCE TO RELATED APPLICATIONS

This application is based upon and claims the benefit of priority from Japanese Patent Application No. 2006-148445, filed on May 29, 2006, the entire contents of which are incorporated herein by reference.

### BACKGROUND

1. Technical Field

The present invention relates to a ferroelectric memory cell and a method of manufacturing a ferroelectric memory cell.

2. Description of the Related Art

There is a ferroelectric memory cell having a 1-transistor 1-capacitor type (1T1C type) structure, which has one transistor for one ferroelectric capacitor in a memory cell. The ferroelectric capacitor is in contact with the transistor via a plug provided just on the transistor. In the ferroelectric capacitor, for example, in case where PZT (lead zirconate titanate) is used as a ferroelectric film, the maximum amount of polarization of PZT is obtained when the (001) plane faces the direction of electric field. However, it is difficult to allow PZT film to have the (001) orientation with a material for use in a common semiconductor integrated circuit. For this reason, the PZT film having (111) orientation, which is easily providing the amount of polarization of PZT, is used for a semiconductor integrated circuit.

In order to obtain highly (111) oriented PZT, it has been the mainstream to use a (111) oriented metal such as Ir or Pt for the layer in contact with PZT. As the method of obtaining the (III) orientation of PZT, a method in which the orientation information of the lower electrode is obtained during PZT crystallization is used. With this method, when the lower electrode is, for example, Pt or Ir, the (111) high orientation of Pt or Ir becomes necessary. Namely, for the lower electrode, a (111) oriented material becomes necessary. This imposes large restrictions on the film type of the lower electrode and the deposition conditions for the film. For example, in the composition region of Zr/Ti=45/55 of PZT which is a ferroelectric substance, the maximum amount of polarization (001) occurs in the c-axis [001] direction perpendicular to the (001) plane. In order to obtain the maximum polarization amount, a c-axis oriented film must be obtained. However, it is very difficult to match the lattice space for obtaining the c-axis orientation with a general semiconductor process.

The ferroelectric film is formed on the lower electrode. In general, the orientation of the ferroelectric film follows the orientation of the lower electrode. Metal such as Pt or Ir is often used for the lower electrode, which includes a crystal structure of FCC (Face Centered Cubic). When such metal is formed on a flat film, the (111) orientation has a priority. Therefore, for a conventional ferroelectric memory cell, a compromise has been made by using the (111) of the lower electrode, and also obtaining the (111) orientation of PZT.

Further, in order for PZT to obtain a strong (111) orientation, a crystallization temperature of high temperature becomes necessary. However, this may adversely affect the characteristics of the semiconductor. Namely, the ferroelectric film requires high temperatures for its crystallization. Therefore, diffusion of elements occurs between the semiconductor substrate and the ferroelectric film during crystallization. This causes the phenomenon of deterioration of both the characteristics of the semiconductor substrate and the ferroelectric film.

In order to prevent the diffusion of elements occurring between the semiconductor substrate and the ferroelectric film, a buffer layer may be provided between the semiconductor substrate and the ferroelectric film. However, this leads a complicated structure, and the characteristics of the ferroelectric film cannot be sufficiently exerted.

Further, prior to the formation of a ferroelectric memory cell, devices such as CMOS are required to be formed. However, the high temperature necessary for the formation of the ferroelectric film deteriorates the characteristics of the devices such as CMOS.

JP-A-11-92266 discloses a thin film formation method. In the method of forming a thin film by a sol-gel process, a monocrystalline nucleus which is to form the thin film is formed on a substrate with a LB (Laser Beam) process. Then, a sol solution is coated on the crystalline nucleus layer, followed by sintering, thereby to form a thin film on the substrate.

JP-A-2004-207304 discloses a ferroelectric capacitor formed by the use of a raw material solution prepared by mixing a sol-gel raw material close in element configuration to the crystal and a MOD (Metal Organic Decomposition) raw material in which the constituent elements move freely easily, and a manufacturing method thereof (see, e.g., Patent Document 2).

### SUMMARY

According to a first aspect of the invention, there is provided a ferroelectric memory cell including: device isolation regions placed in a semiconductor substrate; source/drain regions placed in the semiconductor substrate at a region interposed between the device isolation regions; a gate insulating film placed on the semiconductor substrate at a region interposed between the source/drain regions; a gate electrode placed on the gate insulating film; a first interlayer insulating film formed on the device isolation regions, the source/drain regions and the gate electrode; a contact plug placed in the first interlayer insulating film and connected to one of the source/drain regions; a lower electrode connected to the contact plug and having a first orientation; a ferroelectric film placed on the lower electrode and having a second orientation that is different from the first orientation; an upper electrode placed on the ferroelectric film; a second interlayer insulating film placed on the first interlayer insulating film and the upper electrode; a capacitor contact plug placed in the second interlayer insulating film and connected to the upper electrode; a substrate contact plug placed in the first interlayer insulating film and the second interlayer insulating film and connected to the other one of the source/drain regions; and first and second wiring layers connected to the capacitor contact plug and the substrate contact plug, respectively.

According to a second aspect of the invention, there is provided a ferroelectric memory cell including: device isolation regions placed in a semiconductor substrate; source/drain regions formed in the semiconductor substrate at a region interposed between the device isolation regions; a gate insulating film formed on the semiconductor substrate at a region interposed between the source/drain regions and having a first orientation; a ferroelectric film placed on the gate insulating film and having a second orientation that is different from the first orientation; a gate electrode placed on the ferroelectric film; an interlayer insulating film formed on the device isolation regions, the source/drain regions and the gate electrode; substrate contact plugs formed in the interlayer insulating film and respectively connected to the source/drain regions; and wiring layers connected to the substrate contact plugs, respectively.

According to a third aspect of the invention, there is provided a method of manufacturing a ferroelectric memory cell including: forming device isolation regions in a semiconductor substrate; forming source/drain regions in the semiconductor substrate at a region interposed between the device isolation regions; forming a gate insulating film on the semiconductor substrate at a region interposed between the source/drain regions; forming a gate electrode on the gate insulating film; forming a first interlayer insulating film on the device isolation regions, the source/drain regions and the gate electrode; forming a contact plug to be connected to one of the source/drain regions in the first interlayer insulating film; forming a lower electrode to be connected to the contact plug, depositing a sol-gel solution containing a ferroelectric minute crystal on the lower electrode to form a ferroelectric film; forming an upper electrode on the ferroelectric film; forming a second interlayer insulating film on the first interlayer insulating film and the upper electrode; forming a capacitor contact plug to be connected to the upper electrode in the second interlayer insulating film; forming a substrate contact plug to be connected to the other one of the source/drain regions in the first interlayer insulating film and the second interlayer insulating film; and forming first and second wiring layers to be connected to the capacitor contact plug and the substrate contact plug, respectively.

According a fourth aspect of the invention, there is provided a method of manufacturing a ferroelectric memory cell comprising: forming device isolation regions in a semiconductor substrate; forming source/drain regions in the semiconductor substrate at a region interposed between the device isolation regions; forming a gate insulating film on the semiconductor substrate at a region interposed between the source/drain regions; depositing a sol-gel solution containing a ferroelectric minute crystal on the gate insulating film to form a ferroelectric film; forming a gate electrode on the ferroelectric film; forming an interlayer insulating film on the device isolation regions, the source/drain regions and the gate electrode; forming substrate contact plugs to be respectively connected to the source/drain regions in the interlayer insulating film; and forming wiring layers to be respectively connected to the substrate contact plugs.

### BRIEF DESCRIPTION OF THE DRAWINGS

FIG. 1 is a schematic diagram of a cross-sectional structure of a ferroelectric memory cell according to a first embodiment of the present invention;

FIG. 2 is a schematic diagram of a cross-sectional structure illustrating one process in a method of manufacturing the ferroelectric memory cell according to the first embodiment;

FIG. 3A is an explanatory diagram of the plane direction according to the orientation of a minute crystal;

FIG. 3B is a schematic diagram of a cross-sectional structure illustrating one process in the method according to the first embodiment;

FIG. 4 is a schematic diagram of a cross-sectional structure illustrating one process in the method according to the first embodiment;

FIG. 5 is a schematic diagram of a cross-sectional structure illustrating one process in the method according to the first embodiment;

FIG. 6 is a schematic diagram of a cross-sectional structure illustrating the manner in which a plurality of the ferroelectric memory cells of the first embodiment are arrayed in the direction of a bit line;

FIG. 7 is a circuit configuration diagram of a series connected TC unit type FeRAM cell block in which a plurality of the ferroelectric memory cells of the first embodiment are connected to one another;

FIG. 8 is a schematic block configuration diagram of a series connected TC unit type FeRAM cell array, which is one example of a memory cell array to which the ferroelectric memory cell of the first embodiment is applicable;

FIG. 9 is a schematic block configuration diagram of a 1T1C type FeRAM cell array, which is one example of a memory cell array to which the ferroelectric memory cell of the first embodiment is applicable;

FIG. 10 is a circuit configuration diagram of a 1T type FeRAM to which the ferroelectric memory cell according to the first embodiment is applicable;

FIG. 11 is a schematic diagram of a cross-sectional structure illustrating one step in a method of manufacturing the ferroelectric memory cell according to the second embodiment of the invention;

FIG. 12 is a schematic diagram of a cross-sectional structure illustrating one example in the method of the second embodiment;

FIG. 13 is a schematic diagram of a cross-sectional structure illustrating one example in the method of the second embodiment;

FIG. 14 is a schematic diagram of a cross-sectional structure illustrating one example in the method of the second embodiment;

FIG. 15 is a schematic diagram of a cross-sectional structure of a ferroelectric memory cell of a 1T type MFIS structure according to the second embodiment; and

FIG. 16 is a schematic diagram of a cross-sectional structure of a ferroelectric memory cell of a 1T type MFMIS structure according to the second embodiment

### DETAILED DESCRIPTION

Various embodiments of the present invention will be described with reference to the accompanying drawings. In the following description of the drawings, the same or similar elements are given the same or similar reference numerals and signs. However, it should be noted that the drawings are schematic; and that these are different from the actual ones. Further, it is naturally understood that the dimensional relationships and ratios also differ from one another among some drawings.

Further, the embodiments shown below are for illustrating the devices and methods for embodying the technical idea of the invention. The technical idea of the invention is not to limit the arrangement and the like of respective constituent components to the following ones. Various changes may be made to the technical idea of the invention.

### First Embodiment

(Device Structure)

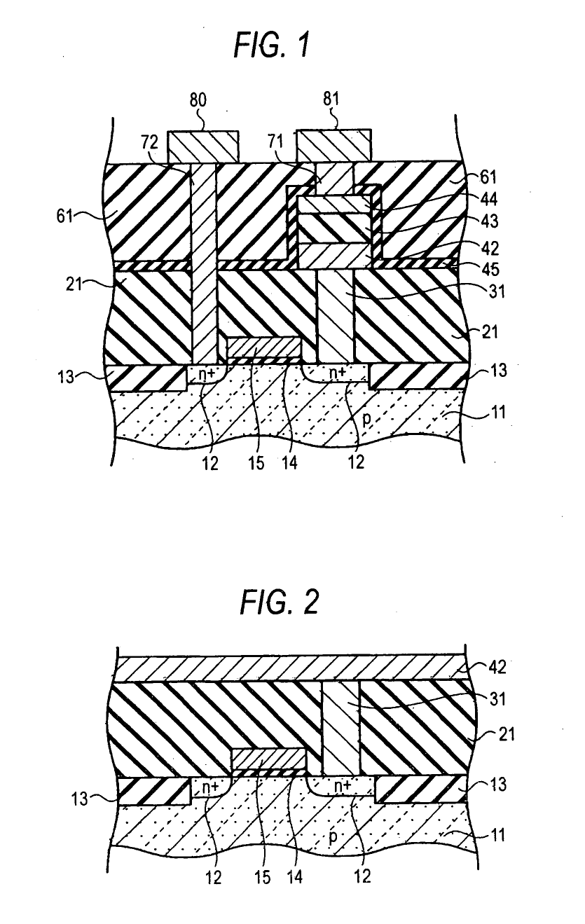

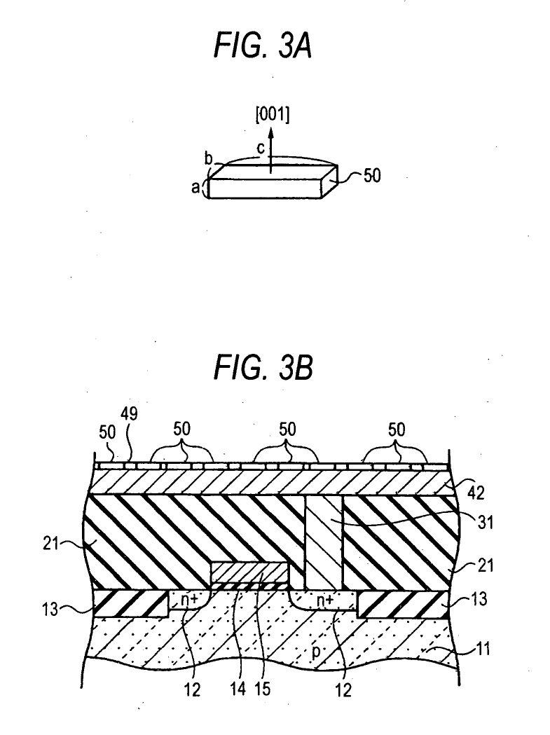

FIG. 1 shows a cross-sectional structure of a ferroelectric memory cell according to a first embodiment of the invention. In the ferroelectric memory cell of the cross section, device isolation regions 13 are placed in a semiconductor substrate 11. Source/drain regions 12 are placed in the semiconductor substrate 11 at a region interposed between the device isolation regions 13. A gate insulating film 14 is placed on the semiconductor substrate 11 at a region interposed between the source/drain regions 12. A gate electrode 15 is placed on the gate insulating film 14. A first interlayer insulating film 21 is placed on the device isolation regions 13, the source/drain regions 12 and the gate electrode 15. A contact plug 31 is placed in the first interlayer insulating film 21 and connected to one of the source/drain region 12. A lower electrode 42 is connected to the contact plug 31, a ferroelectric film 43 is placed on the lower electrode 42, and an upper electrode 44 is placed on the ferroelectric film 43. A second interlayer insulating film 61 is placed on the first interlayer insulating film 21 and the upper electrode 44, A capacitor contact plug 71 is placed in the second interlayer insulating film 61 and connected to the upper electrode 44. A substrate contact plug 72 is placed in the first interlayer insulating film 21 and the second interlayer insulating film 61 and connected to the other one of the source/drain region 12. A first wiring layer 81 and a second wiring layer 80 are connected to the capacitor contact plug 71 and the substrate contact plug 72, respectively. The ferroelectric film 43 is formed by depositing a sol-gel solution containing a ferroelectric minute crystal 50 (see FIG. 3). The ferroelectric film has a lattice mismatch with the lower electrode 42. In this embodiment, the lower electrode 42 has an orientation along (111) plane of a cubic system, and the ferroelectric film 43 has an orientation along (001) plane of a tetragonal system. Hereinafter, “orientation along (lmn) plane” is referred to as “(lmn) orientation.” Herein, a well may be provided in the semiconductor substrate 11 and the device may be formed on the well.

In the first embodiment, the first interlayer insulating film 21, the lower electrode 42, the ferroelectric film 43, and the upper electrode 44 may also be protected by a capacitor protective film 45 as shown in FIG. 1.

In the first embodiment, the film thickness by one-time coating of the sol-gel solution is equal to, or less than the thickness of the shortest side of the ferroelectric minute crystal 50.

(Manufacturing Method)

With reference to FIGS. 2 to 6, a method of manufacturing the ferroelectric memory cell of the first embodiment will be described below.

The method of manufacturing the ferroelectric memory cell according to the first embodiment includes: forming the device isolation regions 13 in the semiconductor substrate 11; forming the source/drain regions 12 in the semiconductor substrate 11 at a region interposed between the device isolation regions 13; forming the gate insulating film 14 on the semiconductor substrate 11 at a region interposed between the source/drain regions 12; forming the gate electrode 15 on the gate insulating film 14; forming the first interlayer insulating film 21 on the device isolation regions 13, the source/drain regions 12, and the gate electrode 15; forming the contact plug 31 to be connected to one of the source/drain region 12 in the first interlayer insulating film 21; forming the lower electrode 42 to be connected to the contact plug 31; depositing a sol-gel solution containing the ferroelectric minute crystal 50 on the lower electrode 42 to form the ferroelectric film 43; forming the upper electrode 44 on the ferroelectric film 43; forming the capacitor protective film 45 on the first interlayer insulating film 21 and the upper electrode 44; forming the second interlayer insulating film 61 on the capacitor protective film 45; forming the capacitor contact plug 71 to be connected to the upper electrode 44 in the second interlayer insulating film 61; forming the substrate contact plug 72 to be connected to the other one of the source/drain regions 12 in the first interlayer insulating film 21 and the second interlayer insulating film 61; and forming the first wiring layer 81 and the second wiring layer 80 which are to be connected to the capacitor contact plug 71 and the substrate contact plug 71, respectively. Herein, a well may be provided in the semiconductor substrate 11 and the device may be formed on the well.

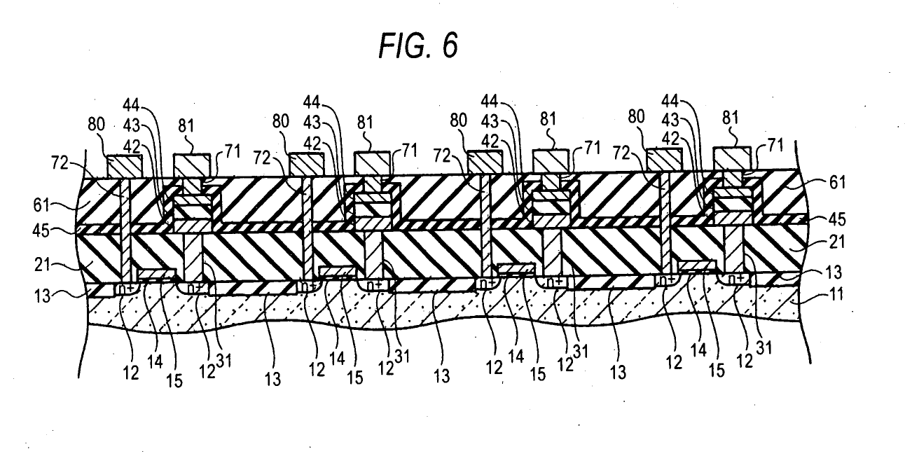

Each of FIGS. 2 to 5 shows a schematic diagram of a cross-sectional structure illustrating a process in a method of manufacturing the ferroelectric memory cell according to the first embodiment. Particularly, FIG. 5A is an explanatory view of the plane direction according to the orientation of the minute crystal. Furthermore, FIG. 6 shows a schematic diagram of a cross-sectional structure illustrating a plurality of the ferroelectric memory cells according to the first embodiment are arranged in a direction of a bit line.

(a) First, as shown in FIG. 2, the device isolation regions 13 are formed in the semiconductor substrate 11. The method of forming the device isolation regions may include a LOCOS (local oxidation of silicon) method, a STI (shallow trench isolation) method, etc. For example, forming the device isolation regions 13 are formed with STI, and the source/drain regions 12 of a memory cell transistor are formed. Further, the gate insulating film 14 and the gate electrode 15 are formed. Then, the first interlayer insulating film 21 is deposited. The manufacturing process for a general MOS transistor or CMOS transistor may be applicable for forming the memory cell transistor.

(b) Then, as shown in FIG. 2, the contact plug 31 for establishing an electrical connection between the lower electrode 42 which is to be formed by deposition later and the source/drain region 12 is formed of, for example, tungsten. The embedding material for the contact plug 31 is desirably tungsten because of the low resistance. However, polysilicon is also applicable.

(c) Then, as shown in FIG. 2, the lower electrode 42 of the ferroelectric capacitor is deposited. In the manufacturing method of the first embodiment, the ferroelectric film 43 is deposited by a process described later, which does not require the lower electrode 42 to have a (111) orientation.

For example, in the first embodiment, an Ir/IrO₂ stacked structure is deposited as the lower electrode 42. The film thicknesses are set at, for example, about 60 nm/about 60 nm, respectively. It is common that the PZT (111) orientation does not occur on the IrO₂ film.

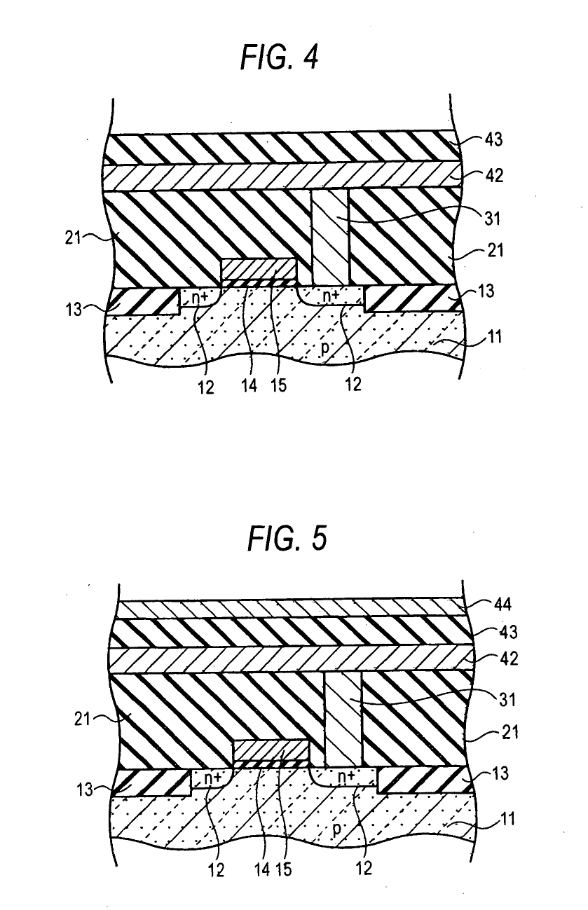

(d) Then, as shown in FIG. 4, on the lower electrode 42, PZT is formed as the ferroelectric thin film 43. In the first embodiment, for example, PZT is taken as an example of the ferroelectric film 43. However, by the similar method, it is possible to form the ferroelectric films 43 containing materials except PZT, such as PLZT (lead lathanium zirconium titanium), SBT (SrBiTaO: strontium-bismuth-tantalum-oxide), BIT (BiTiO; bismuth-titanium oxide), and BLT (BiLaTio: bismuth-lanthanum-titanium-oxide).

—Method of Manufacturing a Ferroelectric Film by a Sol-Gel Process—

Herein, a method of manufacturing a ferroelectric film by a sol-gel process will be described along the following processes (e1) to (e4).

The following sol-gel process is performed for depositing the ferroelectric film 43. As shown in FIG. 3B, on the lower electrode film 42, a sol-gel solution containing the minute crystal 50 of PZT is coated to form the sol-gel coating film 49. For the sol-gel solution, it is possible to use a common commercially available sol-gel solution, as long as the sol-gel solution contains the minute crystal 50 of PZT.

In the first embodiment, the PZT film is formed by, for example, the following method.

(e1) First, the sol that is a raw material for the ferroelectric thin film is formed by the following method.

At first, an appropriate amount of water is added to an alcohol solution of a metal alkoxide to be hydrolyzed. For example, lower alcohols such as ethyl alcohol, isopropyl alcohol, and butyl alcohol, ethylene glycols such as 2-methoxy ethanol, or esters such as isoamyl acetate are used as base solvents.

Then, elements for forming the composition of the ferroelectric film 43 (e.g., PbZr_{0.45}Ti_{0.55}O₃) are stoichiometrically mixed to these base solvents.

For example, titanium tetraisopropoxide (Ti(OC₃H₇)₄), zirconium propoxide (Zr(OC₃H₇)₄), and lead acetate trihydrate (Pb(CH₃COO)₂.3H₂O) are added to the solvent and dissolved therein.

For the amount of the compounds to be dissolved, for example, these organometallic compounds are dissolved in the organic solvent such that the total concentration in terms of metal oxides in the metal oxide thin film forming product is 5 to 20 percent by weight. By using such a method, the sol is formed. Further, the sol is assumed to contain the minute crystal 50 of PZT.

The minute crystal 50 of PZT is configured as follows. For example, as shown in FIG. 3A, it has a shape of rectangular parallelepiped. It is assumed that there is a relationship of a<b<c, where a, b, and c represent the lengths of the respective sides, and that the direction of the plane formed by b and c is (001).

Further, the length of the longest side c is preferably about 20 nm to about 50 nm. This is due to the following fact. When the length of the longest side c is less than 20 nm, the aggregation of the minute crystal 50 tends to occur. When the length is more than 50 nm, there may arise problems in uniformity and flatness of the film.

(e2) Then, the sol-gel solution containing the minute crystal 50 is coated on the lower electrode 42 as shown in FIG. 3B with a film thickness of “a” (shown in FIG. 3A) or less by a spin coating process, thereby forming the sol-gel coating film 49. After coating, the minute crystal 50 becomes stabilized at a position with the lowest potential in terms of gravity and surface energy. Therefore, as shown in FIG. 3A, it becomes stabilized at the point when the plane formed of b and c is directed to the vertical direction.

(e3) Then, the sol-gel coating film 49 is dried at a temperature of from about 75° C. to about 200° C. for about 5 minutes. Then, crystallization is performed at a temperature of about 400° C. under an oxygen atmosphere for about 5 minutes. A general sol-gel process requires a crystallization temperature of about 700° C. However, it is possible to reduce the crystallization temperature in the method of the first embodiment, since a crystal that is to serve as a nucleus has already been present in the sol-gel coating film 49.

(e4) Then, after the crystallization, a cycle of coating-drying-crystallization is performed again. This cycle is repeated until the desired film thickness is formed. As a result, as shown in FIG. 4, the ferroelectric film 43 formed of PZT and having a predetermined thickness is formed. This cycle is performed, for example, until the ferroelectric film 43 of PZT is formed to have a thickness of about 100 nm in the first embodiment. After the crystallization, shrinkage occurs at the gel part. Accordingly, the minute crystal part becomes swollen, and the gel part comes to have a concave shape. However, by performing the cycle of coating-drying-crystallization plural times, it is possible to reduce the level difference to a problem-free level.

After forming the ferroelectric film by the sol-gel process based on the processes (e1) to (e4) described above, the following processes are continued.

(f) After the process (e4), as shown in FIG. 5, as the upper electrode 44, for example, an Ir/IrO₂ stacked film is deposited with thicknesses of about 10 nm/about 20 nm, respectively. As the upper electrode 44, other electrode material such as a single layer of Pt may also be used. In this case, it is necessary to limit the number of cycles to be repeated in view of the fatigue characteristics of repeated writing/reading. Further, as a substitute for the Ir/IrO₂ stacked film, a stacked structure of Pt/SRO or a lamination of Ir/SRO is preferably used. Herein, SRO represents strontium-ruthenium-oxide.

(g) Then, in the structure of FIG. 5, a SiO₂ film as a hard mask layer is deposited with a thickness of about 500 nm by, for example, PECVD (not shown). The hard mask with the SiO₂ film is preferable because it is not affected by the oxidation in the subsequent recovery annealing step. However, as other material, even a Ti type film of TiAlN, TIN, or the like is effective.

(h) Then, the ferroelectric capacitor regions (42, 43, and 44) are patterned by a photolithography process, and the mask layer formed in the process (g) is etched by anisotropic etching. Thereafter, the resist material is removed by a general ashing process.

(i) Then, by using the hard mask layer etched in the process (h) as a mask material, the upper electrode 44, the ferroelectric film 43 and the lower electrode 42 are anisotropically etched. The upper electrode 44, the ferroelectric film 43 and the lower electrode 42 are preferably subjected to anisotropic etching all together by changing the etching conditions according to their respective materials. The cross-sectional structure of FIG. 1 or FIG. 6 shows the ferroelectric capacitor regions (42, 43, and 44) including the upper electrode 44, the ferroelectric film 43 and the lower electrode 42 etched by such anisotropic etching.

(j) Then, in order to remove damages imposed on the ferroelectric capacitor regions by processing, for example, recovery annealing at about 600° C. under an oxygen atmosphere for about 1 hour is performed. This annealing process may be performed under low partial pressure of oxygen or under an atmosphere with no oxygen. Further, it is not necessary to perform this annealing process.

(k) Then, the capacitor protective film 45 acting as a hydrogen barrier film is formed. As the capacitor protective film 45, for example, an Al₂O₃ film is deposited with a thickness of about 20 nm by a CVD process. The cross-sectional structure of FIG. 1 shows the capacitor protective film 45 thus deposited.

(l) Then, the second interlayer insulating film 61 is deposited by, for example, a PECVD process. As the material for the second interlayer insulating film 61, the SiO₂ film can be adopted. The thickness is set at about 1200 nm.

(m) Then, for the second interlayer insulating film 61, for example, a planarization process by CMP or the like is performed so that the portion of the film to be left has a thickness of about 500 nm on the ferroelectric capacitor regions (42, 43, and 44).

(n) Then, a contact hole for the upper electrode 44 is opened by etching.

(o) Then, in order to remove the damages imposed on the ferroelectric capacitor regions (42, 43, and 44) by the working process of the contact hole for the upper electrode 44, for example, recovery annealing at about 600 as and for about 1 hour is performed.

(p) Then, contact holes for the source/drain regions 12 are opened by anisotropical etching through a lithography process.

(q) Then, as shown in FIG. 1, the capacitor contact plug 71 and the substrate contact plug 72 are formed at the same time by embedding and filling a metal in the respective contact holes. The metal to be embedded and filled is preferably formed by forming a Ti/TiN barrier film and then depositing tungsten with a MOCVD process.

(r) Then, as shown in FIG. 1 or FIG. 6, the wiring layer 80 and 81 are formed by using a technique such as sputtering/anisotropic etching, or damascene step.

(s) Subsequently, a general electrode forming process is performed. Namely, an interlayer insulating film is deposited, and via holes and a wiring layer are formed only for the layer in need thereof, thereby forming a ferroelectric memory.

(Examples of Capacitor Stacked Structure)

As the structure of a combination of the ferroelectric film 43 formed of PZT, SBT, etc, the lower electrode 42, and the upper electrode 44, for example, the following structure can be adopted. Namely, as the lower electrode 42, for example, there can be used a Ti/Pt stacked film, a Ti/Pt/SRO stacked film, a Ti/Ir stacked film, a Ti/Ir/SRO stacked film, a Ti/IrO₂/Ir stacked film, a TiAlN/Ir stacked film, a TiAlN/IrO₂/Ir stacked film, a TiAlN/Ir/SRO stacked film, or a TiAlN/IrO₂/Ir/SRO stacked film.

On the other hand, as the upper electrode 44, for example, there can be used Pt, SRO/Pt, an IrO₂ stacked film, an IrO₂/Ir stacked film, a SRO/IrO₂ stacked film, or a SRO/IrO₂/Ir stacked film.

(PZT Orientation Control)

For example, in the composition region of Zr/Ti 45/55 of PZT that is a ferroelectric substance, the maximum amount of polarization occurs in the c-axis [001] direction perpendicular to the (301) plane as shown in FIG. 3A. In order to obtain the maxim polarization amount, a c-axis oriented film must be obtained. However, in the first embodiment, by using a manufacturing method based on a sol-gel process, it is possible to implement the lattice space for obtaining the c-axis orientation, in agreement with a general semiconductor process. The ferroelectric film 43 is formed on the lower electrode 42. In general, the orientation of the ferroelectric film 43 follows the orientation of the lower electrode 42. In other words, the ferroelectric film 43 is generally formed on the lower electrode 42 to have a lattice match with the lower electrode 42.

Metal such as Pt or Ir is often used for the lower electrode, which includes a crystal structure of FCC (Face Centered cubic). When such metal is formed on a flat film, the (111) orientation has a priority. Therefore, when PZT also have (111) orientation in accordance with the (111) orientation of the lower electrode, the theoretical amount of polarization of the PZT (111) orientation is about 58% of the PZT (111) orientation.

In the first embodiment, by using a manufacturing method based on a sol-gel process, it is possible to obtain the PZT (001) orientation with stability, since the ferroelectric film (e.g., PZT, in this embodiment) having a lattice mismatch with a lower layer of the ferroelectric film (e.g., the lower electrode 42, in this embodiment). Therefore, theoretically, it is possible to increase the amount of polarization by about 72%.

(Memory Cell Array)

The ferroelectric memory cell of the first embodiment may particularly be applied to a series connected TC unit type chain ferroelectric memory (chain FeRAM) including a plurality of memory cells in each of which both the electrodes of a ferroelectric capacitor are connected to the source/drain regions of a MOS transistor, or a 1-transistor 1-capacitor type ferroelectric memory (1T1C type FeRAM).

(Series Connected TC Unit Type)

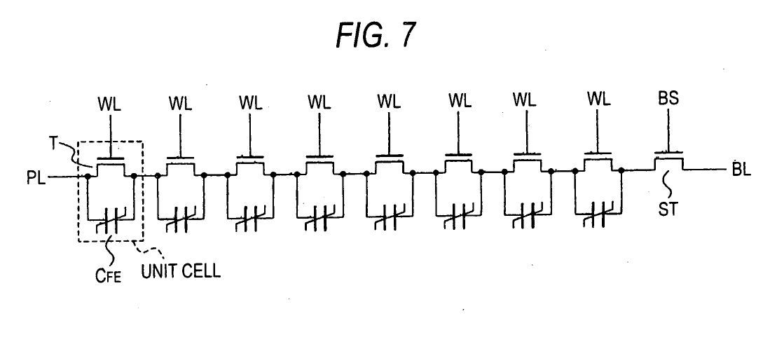

As shown in FIG. 7, the series connected TC unit type FeRAM includes, for example, a unit cell in which the opposite ends of the ferroelectric capacitor Cad are connected between the source/drain of a cell transistor T, respectively. A plurality of the unit cells are arranged in series between a plate line PL and a bit line BL as shown in FIG. 7. The block of a series connected TC unit type FeRAM string including a plurality of cells connected in series is selected by a block select transistor ST. A word line WL is connected to the gates of respective cell transistors T. A block select line ES is connected to the gate of the block select transistor ST.

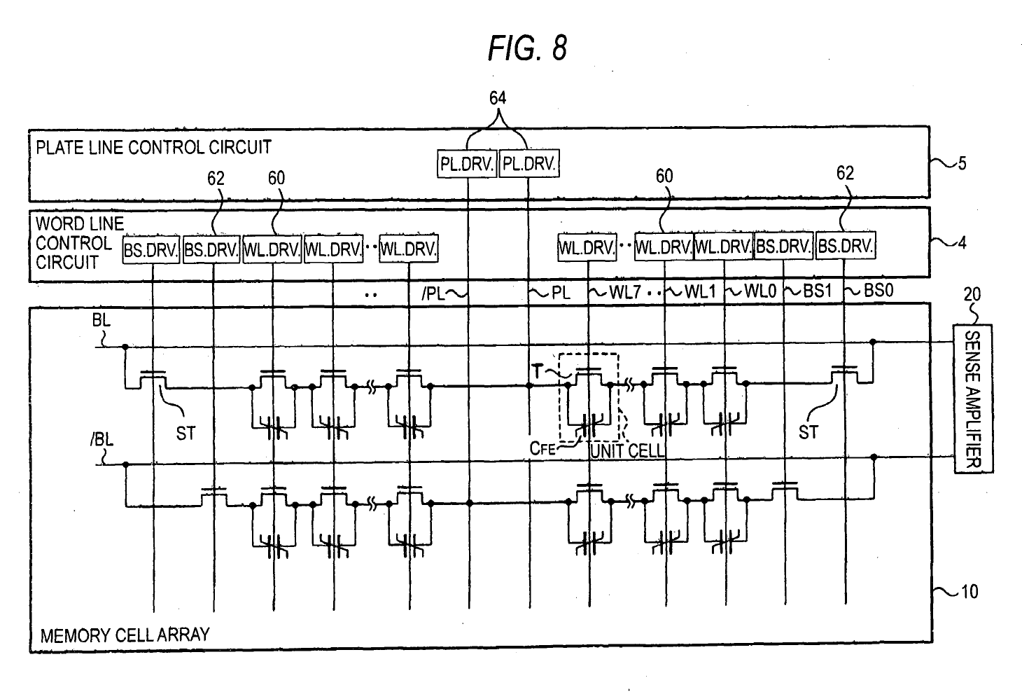

As an example of the memory cell array, the ferroelectric memory cell of the first embodiment is applicable to a series connected TC unit type FeRAM cell array as shown in FIG. 8.

As shown in FIG. 8, the series connected TC unit type FeRAM cell array includes a memory cell array 10, a word line control circuit 4 connected to the memory cell array 10, and a plate line control circuit 5 connected to the memory cell array 10. In the memory cell array 10, as shown in FIG. 8, a plurality of series connected TC unit type FeRAM cells are arrayed in a matrix.

As shown in FIG. 8, a plurality of word lines WL (WL0 to WL7) are respectively connected to word line drivers (WL. DRV.) 60 arranged in the word line control circuit 4. The block select lines BS (BS0, BS1) are respectively connected to block select line drivers (BS. DRV.) 62 arranged in the word line control circuit 4. The plate lines PL (PL, /PL) are respectively connected to plate line drivers (PL. DRV.) 64 arranged in the plate line control circuit 5.

In the memory cell array 101 as shown in FIG. 8, blocks of the series connected TC unit type FeRAM are arranged in parallel to each other in the direction of extension of the word lines WL (WL0 to WL7). Further, the memory cell array 10 has a configuration in which, as shown in FIG. 8, the blocks of series connected TC unit type FeRAM are folded back in the direction of extension of the bit lines BL (BL, /BL) with the plate lines PL(PL, /PL) as the center.

In the series connected TC unit type FeRAM, the potential of the word lines WL (WL0 to WL7) and the potential of the block select lines BS (BS0, BS1) is set at, for example, either an internal power source VPP or a circuit ground potential GND (e.g., 0 V). In a standby state, for example, the potential of the word lines WL and the block select lines BS is set as follows: WL=VPP, BS=GND. The potential of the plate lines PL (PL, /PL) is set at either of the internal power source VINT or the circuit ground potential GND. In a standby state, the potential of the plate lines PL is set as follows: PL=GND. The bit lines EL (BL, /BL) are connected with a sense amplifier 20, so that the electric charge read from the FeRAM cell is transferred thereto. In a standby state, BL=GND.

(1-Transistor 1-Capacitor Type)

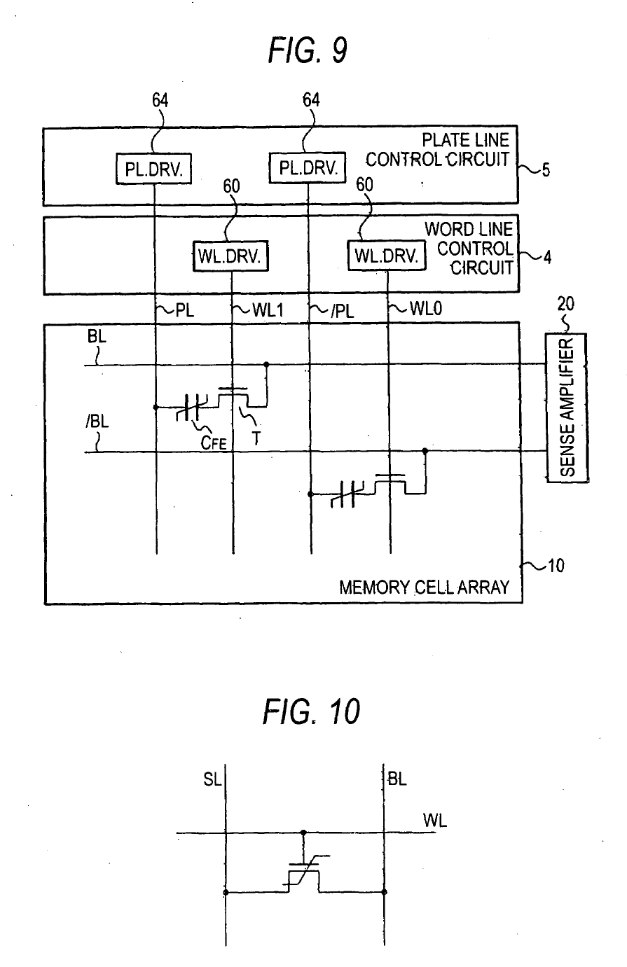

As an example of other memory cell array, the ferroelectric memory cell of the first embodiment is applicable to a 1T1C type FeRAM as shown in FIG. 9.

As shown in FIG. 9, the 1T1C type FeRAM includes the memory cell array 10, the word line control circuit 4 connected to the memory cell array 10, and the plate line control circuit 5 connected to the memory cell array 10. In the memory cell array 10, a plurality of the 1T1C type FeRAM cells are integrated.

As shown in FIG. 9, 1T1C type FeRAM includes, for example, a unit cell including a ferroelectric capacitor C_{FE} connected in series to the source of the cell transistor T. The unit cells are each disposed at the parts of intersection between a plurality of the plate lines PL (PL, /PL) and a plurality of bit lines BL (BL, /BL) as shown in FIG. 9, thus forming a matrix.

Each of the cell transistors T includes a gate connected to the word line Wt. Each of the ferroelectric capacitors C_{FE} includes an electrode connected to the source of the cell transistor T, and the other electrode connected to the plate lines PL (PL, /PL). The drains of the cell transistors T are connected to the bit lines BL (BL, /BL).

As shown in FIG. 9, a plurality of the word lines WL (WL0, WL1, and the like) are respectively connected to the word line drivers (WL. DRV.) 60 arranged in the word line control circuit 4. The plate lines PL (PL, /PL) are respectively connected to the plate line drivers (PL. DRV.) 64 arranged in the plate line control circuit 5.

In the 1T1C type FeRAM, the potential of the word lines is set at, for example, either an internal power source VPP or a circuit ground potential GND (e.g., 0 V). In a standby state, for example, the potential of the word lines WL is set as follows: WL=VPP. The potential of the plate lines PL (PL, /PL) is set at either the internal power source VINT or the circuit ground potential GND. In a standby state, the potential of the plate lines PL is set as follows: PL=GND. The bit lines BL (BL, /BL) are connected with the sense amplifier 20, so that the electric charge read from the 1T1C type FeRAM cell is transferred thereto. In a standby state, BL=GND.

According to the ferroelectric memory cell and the manufacturing method thereof of the first embodiment of the invention, by adopting the ferroelectric film using a sol-gel solution containing a minute crystal as a raw material, orientation of the ferroelectric film is excellently controlled, and the ferroelectric film can be formed at low temperatures. As a result, the film quality is improved, and the manufacturing yield is improved. Thus, it is possible to achieve high withstand voltage and low leak current ferroelectric memory characteristics.

### Second Embodiment

(1-Transistor Type)

The ferroelectric memory cell according to a second embodiment of the invention is applied to a 1-transistor type ferroelectric memory (1T type FeRAM).

A circuit configuration of the ferroelectric memory cell of the second embodiment is illustrated as shown in FIG. 10. Namely, the source region is connected to the source line SL, and the drain region is connected to the bit line. Thus, the MOS gate capacitor structure of the MOS transistor is formed of a ferroelectric capacitor structure made of a ferroelectric material, and the MOS gate electrode is connected with the word line WL. The structures of 1T type FeRAM as shown in FIG. 10 are arranged in a matrix, thereby to form the memory cell array.

(Device Structure)

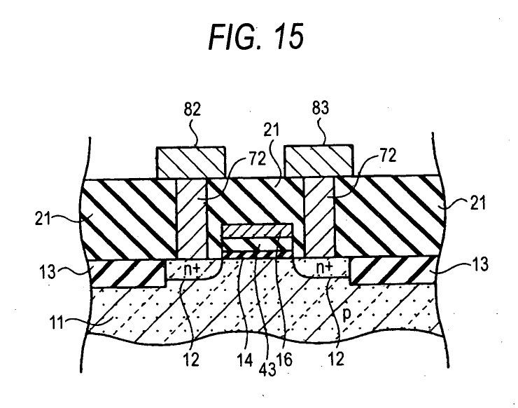

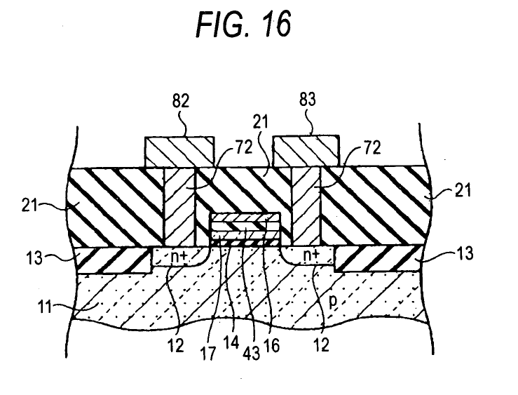

The cross-sectional structure of the ferroelectric memory cell of the second embodiment is schematically illustrated as shown in FIG. 15. It is a ferroelectric memory of a 1T type MFIS (metal-ferroelectric film-insulating film-semiconductor) including a ferroelectric thin film and a gate electrode on a semiconductor substrate. As shown in FIG. 15, in the ferroelectric memory cell, device isolation regions 13 are formed in a semiconductor substrate 11, source/drain regions 12 are formed in the semiconductor substrate 11 at a region interposed between the device isolation regions 13. A gate insulating film 14 is formed on the semiconductor substrate 11 at a region interposed between the source/drain regions 12, a ferroelectric film 43 is placed on the gate insulating film 14, and a gate electrode 16 is placed on the ferroelectric film 43. The gate insulating film 14 is provided as a lower layer of the ferroelectric film 43. A first interlayer insulating film 21 is placed on the device isolation regions 13, the source/drain regions 12, and the gate electrode 16. Substrate contact plugs 72 are formed in the first interlayer insulating film 21 and connected to the source/drain regions 12. Wiring layers 82 and 83 are connected to the substrate contact plugs 72. The ferroelectric film 43 is formed by depositing a sol-gel solution containing a ferroelectric minute crystal 50. The ferroelectric film 43 has a lattice mismatch with the gate insulating film 14. In this embodiment, the ferroelectric film 43 has an orientation along (111) plane of a tetragonal system. Herein, a well may be provided in the semiconductor substrate 11 and the device may be formed on the well.

In the ferroelectric memory cell of the second embodiment, the film thickness by one-time coating of the sol-gel solution is equal to or less than the thickness of the shortest side of the ferroelectric minute crystal 50.

(Manufacturing Method)

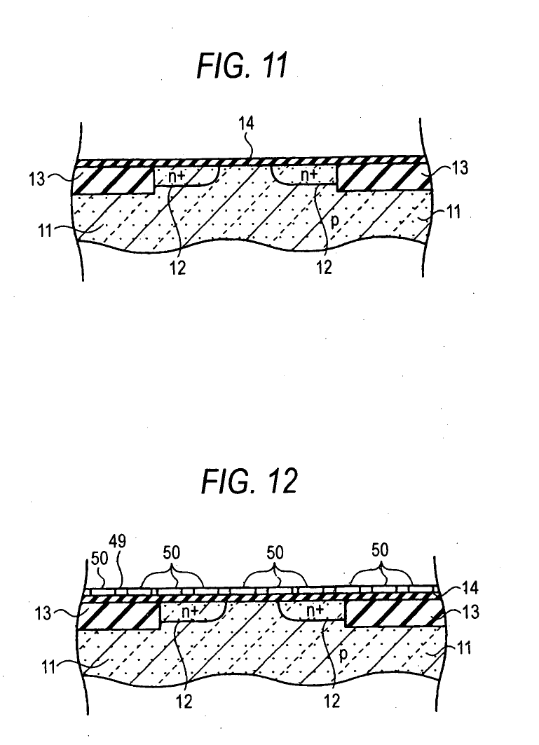

With reference to FIGS. 11 to 15, a method of manufacturing the ferroelectric memory cell of the second embodiment will be described below.

The method of manufacturing the ferroelectric memory cell of the second embodiment includes: forming the device isolation regions 13 in the semiconductor substrate 11; forming the source/drain regions 12 in the semiconductor substrate 11 interposed between the device isolation regions 13; forming the gate insulating film 14 on the semiconductor substrate 11 interposed between the source/drain regions 12, depositing a sol-gel solution containing the ferroelectric minute crystal 50 on the gate insulating film 14 to form the ferroelectric film 43; forming the gate electrode 16 on the ferroelectric film 43; forming the interlayer insulating film 21 on the device isolation regions 13, the source/drain regions 12, and the gate electrode 16; forming the substrate contact plug 72 to be connected to the source/drain regions 12 in the interlayer insulating film 21; and forming the wiring layers 82 and 83 which are to be connected to the substrate contact plugs 72. Herein, a well may be provided in the semiconductor substrate 11 and the device may be formed on the well.

Each of FIGS. 11 to 15 shows a schematic diagram of a cross-section structure illustrating a process in the method of manufacturing the ferroelectric memory cell according to the second embodiment of the invention.

(a) First, as shown in FIG. 11, in the p-type semiconductor substrate 11, the device isolation regions 13 formed with STI and the source/drain regions 12 of the memory cell transistor are formed. The manufacturing process for a general MOS transistor or CMOS transistor may be applicable for forming the memory cell transistor. At the same time of forming the memory cell transistor, devices such as CMOS (not shown) are formed on the active semiconductor substrate 11. These are the parts to be the logical circuit region of the ferroelectric memory cell part to be formed later.

Thereafter, on a region of the previously left active semiconductor substrate 11, the gate insulating film 14 is deposited. For the gate insulating film 14, for example, when the semiconductor substrate 11 is silicon, the silicon oxide obtainable by oxidizing silicon is the most easily obtainable insulating film. Since a thin insulating film is necessary, as other insulating films, aluminum oxide, hafnium oxide, or a composite film of aluminum oxide and hafnium oxide is preferable from the standpoint of the reduction of the leak current.

(b) Then, as shown in FIG. 12, the ferroelectric thin film 43 is formed on the gate insulating film 14. In this embodiment, for example, BIT is taken as an example of the ferroelectric film 43. However, the ferroelectric films 43 having other constituent materials such as SBT, BLT, and PZT can also be formed by adopting the same method.

—Method of Manufacturing a Ferroelectric Film by a Sol-Gel Process—

Herein, a method of manufacturing a ferroelectric film by a sol-gel process will be described along the following processes (c1) to (c4).

The following sol-gel process is performed for depositing the ferroelectric film 43. As shown in FIG. 12, a sol-gel solution containing the minute crystal 50 of BIT is coated on the gate insulating film 14 to form the sol-gel coating film 49. For the sol-gel solution itself, it is possible to use a common commercially available sol-gel solution, as long as the sol-gel solution contains the minute crystal 50 of BIT.

In this embodiment, the BIT film is formed by, for example, the following method.

(c1) First, the sol that is a raw material for the ferroelectric thin film is formed by the following method.

At first, an appropriate amount of water is added to an alcohol solution of a metal alkoxide to be hydrolyzed. For example, lower alcohols such as ethyl alcohol, isopropyl alcohol, and butyl alcohol, ethylene glycols such as 2-methoxy ethanol, or esters such as isoamyl acetate are used as base solvents.

The, elements for forming the composition of the ferroelectric film 43 are stoichiometrically mixed to these base solvents.

For the amount of the compounds to be dissolved, for example, the organometallic compounds such as Bi and Ti are dissolved in the organic solvent such that the total concentration in terms of metal oxides in the metal oxide thin film forming product is 5 to 20 percent by weight. By using such a method, the sol is formed. Further, the sol is assumed to contain the minute crystal 50 of BIT.

The minute crystal 50 of BIT is configured as follows. For example, as with FIG. 3A shown in the first embodiment, it has a shape of rectangular parallelepiped. It is assumed that there is a relationship of a<b<c, where a, b, and c represent the lengths of the respective sides, and that the direction of the plane formed by b and c is (001).

Further, the length of the longest side c is desirably about 20 nm to about 50 nm. This is due to the following fact. When the length of the longest side c is less than 20 nm, the aggregation of the minute crystal 50 tends to occur. When the length is more than 50 nm, there may arise problems in uniformity and flatness of the film.

(c2) Then, the sol-gel solution containing the minute crystal 50 is coated on the gate insulating film 14 as shown in FIG. 12 with a film thickness of “a” (shown in FIG. 3A) or less by a spin coating process, thereby to form the sot-gel coating film 49. After coating, the minute crystal 50 becomes stabilized at a position with the lowest potential in terms of gravity and surface energy. Therefore, as with FIG. 3A, it becomes stabilized at the point when the plane formed of b and c is directed to the vertical direction.

(c3) Then, the sol-gel coating film 49 is dried at a temperature of from about 75° C. to about 200° C. for about 5 minutes. Then, crystallization is performed at a temperature of about 400° C. under an oxygen atmosphere for about 5 minutes. A general sol-gel process requires a crystallization temperature of about 700° C. However, it is possible to reduce the crystallization temperature in the method of the second embodiment, since a crystal which is to serve as a nucleus has already been present in the sol-gel coating film 49.

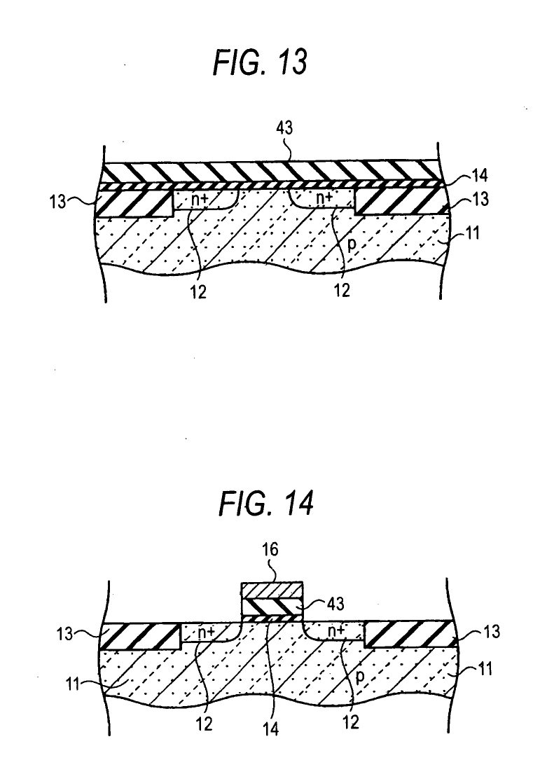

(c4) Then, after the crystallization, a cycle of coating-drying-crystallization is performed again. This cycle is repeated until the desired film thickness is formed. As a result, as shown in FIG. 13, the ferroelectric film 43 formed of BIT and having a prescribed thickness is formed. This cycle is performed, for example, until the ferroelectric film 43 of BIT is formed to have a thickness of about 100 nm in this embodiment. After the crystallization, shrinkage occurs at the gel part. Accordingly, the minute crystal part becomes swollen, and the gel part comes to have a concave shape. However, by performing the cycle of coating-drying-crystallization plural times, it is possible to reduce the level difference to a problem-free level.

The layer of BIT crystal obtained by such processes has a (001) orientation. The maximum polarization axis of BIT is along the direction of “a” axis, and a value of about 40 μC/cm² can be obtained. However, when the layer has such a high polarization amount, leakage of electric charges tends to occur between the semiconductor substrate 11 and the ferroelectric film 43. This shortens the retention time of the ferroelectric memory. For this reason, as the ferroelectric film 43 to be applied to a MFIS structure, it is preferable to have a small polarization amount. For BIT, there is a polarization amount of only about 4 μC/cm² in the direction of “c” axis. Therefore, the direction of “c” axis is excellent in characteristic from the viewpoint of the leakage characteristic. For such a reason, in this embodiment, a BIT film strongly oriented in the direction of “c” axis is formed.

After forming the ferroelectric film by the so-gel process based on the processes (c1) to (c4) described above, the following processes are continued.

(d) After the process (c4), the gate electrode 16 is formed on the ferroelectric film 43. The gate electrode 16 is preferably a noble metal film such as Pt, Au, etc, which does not lose the conductivity by oxidation with the ferroelectric film 43 which is an oxide, Also, the gate electrode 16 is preferably a conductive film of an oxide such as IrO₂ or RuO₂, which does not lose conductivity despite being an oxide. Still further, the gate electrode 16 is preferably a composite film of the above films. When a monolayer of Pt is used, it is necessary to limit the number of cycles to be repeated in view of the fatigue characteristics of repeated writing/reading.

Alternatively, as the gate electrode 16, for example, an Ir/IrO₂ stacked film may also be deposited with a film thickness of about 10 nm/about 20 nm, respectively. Further, as a substitute for the Ir/IrO₂ stacked film, a stacked structure of Pt/SRO, or a lamination of Ir/SRO may be used.

(e) Then, an insulating film of a silicon oxide or the like is deposited on the gate electrode 16. For example, a SiO₂ film is deposited with a thickness of about 500 nm by a CVD method (not shown).

(f) Then, as shown in FIG. 14, a gate part of the memory cell transistor is formed by lithography. Namely, by using a photoresist film as a mask, the SiO₂ film is processed by anisotropic etching. After removing the photoresist by an ashing process, by using the SiO₂ film as a mask material, the lower gate electrode 16 and the ferroelectric film 43 are etched. The etching step may be completed by leaving the gate insulating film 14.

(g) Then, using the gate region including the gate electrode 16 and the ferroelectric film 43 as a mask, ion implantation is performed. By the ion implantation, it is possible to form the source/drain regions with a high concentration in a self-alignment manner. Namely, for the source/drain regions 12 previously formed in the step (a), the source/drain regions with a further higher concentration can be formed shallowly. As a result, it is also possible to implement a LDD (Lightly Doped Drain) structure.

(h) Then, the first interlayer insulating film 21 is deposited by, for example, a PECVD process. As the material for the first interlayer insulating film 21, a SiO₂ film can be used. The thickness is set at about 1200 nm.

(i) Then, for the first interlayer insulating film 21, for example, a planarization step by CMP or the like is performed so that the portion of the film to be left has a thickness of about 500 nm on the gate electrode 16.

(i) Then, the contact holes for the drain region 12 are opened by anisotropic etching through a lithography step.

(k) Then, as shown in FIG. 15, the substrate contact plugs 72 are formed by embedding and filling a metal in their respective contact holes. The metal to be embedded and filled is preferably formed by forming a Ti/TiN barrier film and then depositing tungsten with a MOCVD process.

(l) Then, as shown in FIG. 15, the wiring layers 82 and 83 formed of a metal such as Al or Cu are formed by a deposition process and a patterning process.

(m) Subsequently, a general electrode forming process is performed. Namely, an interlayer insulating film is deposited, and via holes and a wiring layer are formed only for the layer in need thereof, thereby to form a ferroelectric memory.

According to the ferroelectric memory cell and the manufacturing method thereof of the second embodiment of the invention, by adopting the ferroelectric film using a sol-gel solution containing a minute crystal as a raw material, orientation of the ferroelectric film is excellently controlled, and the ferroelectric film can be formed at low temperatures. As a result, the film quality is improved, and the manufacturing yield is improved. Thus, it is possible to achieve high withstand voltage and low leak current ferroelectric memory characteristics.

Although the ferroelectric memory of a IT type MFIS is explained in the second embodiment, the ferroelectric of the second embodiment may have a IT type MFMIS (metal-ferroelectric film-metal-insulating film-semiconductor) structure.

As shown in FIG. 16, the ferroelectric memory of the 1T type MFMIS includes a metal layer 17 as a lower layer of the ferroelectric 43. That is, the metal layer 17 is formed between the gate insulating film 14 and the ferroelectric film 43. The metal layer 17 and the gate electrode 16 act as a floating gate and a control gate of a transistor in the ferroelectric memory cell, respectively.

The ferroelectric film 43 is formed on the metal layer 17 by similar processes (c1) to (c4) explained in the second embodiment. Accordingly, the ferroelectric film 43 has the lattice mismatch with the metal layer 17.

### Other Embodiments

As described above, the description was made by way of the first and second embodiments. However, it is to be understood that the invention is not limited to the description and the drawings as a part of the disclosure. From the disclosure, various alternate embodiments, examples, and operational techniques would be obvious to those skilled in the art.

Thus, it is naturally understood that the invention includes various embodiments and the like not herein described,

What is claimed is:

1. A ferroelectric memory cell comprising:
device isolation regions placed in a semiconductor substrate;
source/drain regions placed in the semiconductor substrate at a region interposed between the device isolation regions;
a gate insulating film placed on the semiconductor substrate at a region interposed between the source/drain regions;
a gate electrode placed on the gate insulating film;
a first interlayer insulating film formed on the device isolation regions, the source/drain regions and the gate electrode;
a lower electrode placed on the first interlayer insulating film;
a ferroelectric film placed on the lower electrode and having a lattice mismatch with the lower electrode; and
an upper electrode placed on the ferroelectric film.

2. The memory cell according to claim 1, wherein the lower electrode has an orientation along (111) plane of a cubic system, and the ferroelectric film has an orientation along (001) plane of a tetragonal system.

3. The memory cell according to claim 1, wherein the lower electrode includes one of an Ir/IrO₂ stacked film, a Ti/Pt stacked film, a Ti/Pt/SRO stacked film, a Ti/Ir stacked film, a Ti/Ir/SRO stacked film, a Ti/IrO₂/Ir stacked film, a TiAlN/Ir stacked film, a TiAlN/IrO₂/Ir stacked film, a TiAlN/Ir/SRO stacked film and a TiAlN/IrO₂/Ir/SRO stacked film, and
wherein the ferroelectric film includes one of lead zirconate titanate film, lead lathanium zirconium titanium film, SrBiTaO film, BiTiO film and BiLaTio film.

4. The memory cell according to claim 1, the ferroelectric film is formed by depositing a sol-gel solution containing a ferroelectric minute crystal.

5. The memory cell according to claim 1, further comprising:
a contact plug placed in the first interlayer insulating film and connected between one of the source/drain regions and the lower electrode;
a second interlayer insulating film placed on the first interlayer insulating film and the upper electrode;
a capacitor contact plug placed in the second interlayer insulating film and connected to the upper electrode;
a substrate contact plug placed in the first interlayer insulating fim and the second interlayer insulating film and connected to the other one of the source/drain regions; and
first and second wiring layers connected to the capacitor contact plug and the substrate contact plug, respectively.

6. A ferroelectric memory cell comprising:
device isolation regions placed in a semiconductor substrate;
source/drain regions formed in the semiconductor substrate at a region interposed between the device isolation regions;
a lower layer formed on the semiconductor substrate at a region interposed between the source/drain regions;
a ferroelectric film placed on the lower layer and having a lattice mismatch with the lower layer; and
a gate electrode placed on the ferroelectric film.

7. The memory cell according to claim 6,
wherein the lower layer comprises: a gate insulating film formed on the semiconductor substrate; and a metal layer formed between the gate insulating film and the ferroelectric film, and
wherein the ferroelectric film has the lattice mismatch with the metal layer.

8. The memory cell according to claim 6,
wherein the lower layer comprises a gate insulating film formed between the semiconductor substrate and the ferroelectric film, and
wherein the ferroelectric film has the lattice mismatch with the gate insulating film.

9. The memory cell according to claim 6, wherein the ferroelectric film has an orientation along (001) plane of a tetragonal system.

10. The memory cell according to claim 6, wherein the gate insulating film includes one of a SiO₂ film, aluminum oxide film, hafnium oxide film and a composite film of aluminum oxide and hafnium oxide, and
wherein the ferroelectric film includes one of lead zirconate titanate film, lead lathanium zirconium titanium film, SrBiTaO film, BiTiO film and BiLaTiO film.

11. The memory cell according to claim 6, the ferroelectric film is formed by depositing a sol-gel solution containing a ferroelectric minute crystal.

12. The memory cell according to claim 6, further comprising:
an interlayer insulating film formed on the device isolation regions, the source/drain regions and the gate electrode;
substrate contact plugs formed in the interlayer insulating film and respectively connected to the source/drain regions; and
wiring layers connected to the substrate contact plugs, respectively.

13. A method of manufacturing a ferroelectric memory cell comprising:
forming device isolation regions in a semiconductor substrate;
forming source/drain regions in the semiconductor substrate at a region interposed between the device isolation regions;
forming a gate insulating film on the semiconductor substrate at a region interposed between the source/drain regions;
forming a gate electrode on the gate insulating film;
forming a first interlayer insulating film on the device isolation regions, the source/drain regions and the gate electrode;
forming a lower electrode on the first interlayer insulating film;
depositing a sol-gel solution containing a ferroelectric minute crystal on the lower electrode to form a ferroelectric film; and
forming an upper electrode on the ferroelectric film.

14. The method according to claim 13, wherein said depositing the sol-gel solution comprises:
coating the sol-gel solution to form a sol-gel film having a thickness equal to or less than a length of a shortest side of the ferroelectric minute crystal; and
repeating said coating the sol-gel solution to form the ferroelectric film of a predetermined thickness.

15. The method according to claim 14, wherein said depositing the sol-gel solution comprises:
said coating the sol-gel solution to form the sol-gel film,
drying the sol-gel film;
crystallizing the sol-gel film; and
repeating said coating, said drying and said crystallizing to form the ferroelectric film of the predetermined thickness.

16. The method according to claim 15, wherein said crystallizing the sol-gel coating film is performed at a temperature of about 400° C.

17. The method according to claim 15, wherein a length of a longest side of the ferroelectric minute crystal is 20 to 50 nm.

18. The method according to claim 15, wherein the gate electrode includes one of an Ir/IrO₂ stacked film, a Ti/Pt stacked film, a Ti/Pt/SRO stacked film, a Ti/Ir stacked film, a Ti/Ir/SRO stacked film, a Ti/IrO₂/Ir stacked film, a TiAlN/Ir stacked film, a TiAlN/IrO₂/Ir stacked film, a TiAlN/Ir/SRO stacked film and a TiAlN/IrO₂/Ir/SRO stacked film, and
wherein the ferroelectric film includes one of lead zirconate titanate film, lead lathanium zirconium titanium film, SrBiTaO film, BiTiO film and BiLaTiO film.

19. The method according to claim 13, further comprising:
forming a contact plug to be connected between one of the source/drain regions and the lower electrode in the first interlayer insulating film;
forming a second interlayer insulating film on the first interlayer insulating film and the upper electrode;
forming a capacitor contact plug to be connected to the upper electrode in the second interlayer insulating film;
forming a substrate contact plug to be connected to the other one of the source/drain regions in the first interlayer insulating film and the second interlayer insulating film; and
forming first and second wiring layers to be connected to the capacitor contact plug and the substrate contact plug, respectively.
